(19) United States
(12) Patent Application Publication
(10) Pub. No.: US 2011/0026562 A1
(43) Pub. Date: Feb. 3, 2011

(54) TEMPERATURE SENSOR USING THIN FILM RESISTANCE TEMPERATURE DETECTOR

(75) Inventors: Peter David Bernier, Minneapolis, MN (US); Jonathan Spencer Shogren, Andover, MN (US); Brant Robert Kochsiek, Minneapolis, MN (US)

Correspondence Address: SCHWEGMAN, LUNDBERG & WOESSNER, P.A., P.O. BOX 2938, MINNEAPOLIS, MN, 55402, US

(73) Assignee: RTD Company, Ham Lake, MN (US)

(21) Appl. No.: 12/847,815

(22) Filed: Jul. 30, 2010

Related U.S. Application Data
(60) Provisional application No. 61/230,421, filed on Jul. 31, 2009.

(51) Int. Cl. G01K 7/16; H05K 13/00

(52) U.S. Cl. 374/184; 29/592.1; 374/E07.018

(57) ABSTRACT

The present subject matter relates generally to temperature sensors using a thin film element. Various embodiments of the present subject matter include a temperature sensor assembly. The temperature sensor assembly includes an enclosure having an inside surface and a thin film element housed in the enclosure. A thermally conductive material connects a surface of the thin film element directly to the inside surface of the enclosure in a side mounted manner to provide rapid thermal conduction from the enclosure to the thin film element. In various embodiments, the thin film element is a resistance temperature detector (RTD).

### CLAIM OF PRIORITY

The present application claims the benefit under 35 U.S.C. 119(e) of U.S. Provisional Patent Application Ser. No. 61/230,421, filed Jul. 31, 2009, which is hereby incorporated by reference in its entirety.

### FIELD OF THE INVENTION

The present subject matter relates generally to temperature sensors, and in particular to temperature sensors using thin film elements, such as thin film resistance temperature detectors (RTDs).

### BACKGROUND

Temperature sensors are used to measure temperature of liquids. When used in conjunction with a control system for heating or cooling, the temperature sensor must be able to provide an accurate temperature measurement within a limited amount of time to avoid excessive overshoot or instability in the control loop. Temperature sensors that experience large temperature variations need to be robust to prevent failures.

Some known control systems for high temperature fluid measurement, such as vat fryers heating oil to frying temperature, include simple snap acting switches or thermostats. More complex systems, such as larger fryers used in commercial and industrial food preparation, may use signals from RTDs and thermocouples. These more sophisticated fryers need consistently controlled oil temperature to assure meeting specific heating cycles and heating algorithms based on what product is being cooked. Heating cycles that occur too slowly or too quickly after the food is introduced into the fryer result in poor quality (i.e., burned chicken or soggy French fries).

One approach to temperature sensing includes a hollow wound RTD sensor which is a resistance temperature detector wound around a steel mandrel, soldered, and inserted into a stainless steel tube with a thin wall. The combination of the hollow wound element and thin wall tubing results in a fast response (for example, a response of 1.6 seconds per ASTM E644 Time Response Test) system that meets the cooking needs. However, such designs frequently involve numerous electro-mechanical connections (soldered, or welded, or brazed) and may lack reliability.

There is a need in the art for a reliable temperature sensor that provides reasonably accurate temperature measurement within a desired response time. The sensor should be straightforward to manufacture and relatively cost effective.

### SUMMARY

Disclosed herein, among other things, are methods and apparatus for temperature sensors using thin film elements. In various embodiments the thin film elements include resistance temperature detectors (RTDs) that are mounted to the side of an enclosure. Such embodiments provide accurate temperature measurement within a desired response time. The sensors are relatively straightforward to manufacture and such designs are cost effective and reliable.

Various embodiments of the present subject matter include a temperature sensor using a thin film resistance temperature detector (RTD) housed in a metal enclosure in a side mounted manner. The thin film RTD has a surface that is connected to the metal enclosure to provide rapid thermal conduction from the metal enclosure to the thin film RTD by minimizing the mass of the heat sensing materials and surrounding structure, using high heat transfer adhesives and/or potting materials, and directly mounting the sensor to the side of the enclosure.

Various embodiments of the present subject matter include a temperature sensor assembly. The temperature sensor assembly includes an enclosure having an inside surface and a thin film element housed in the enclosure. A thermally conductive material connects a surface of the thin film element directly to the inside surface of the enclosure in a side mounted manner to provide rapid thermal conduction from the enclosure to the thin film element.

Various embodiments of the present subject matter include a method of making a temperature sensor assembly. A thin film resistance temperature detector (RTD) is connected directly to the inside surface of a thin-walled cylindrical metal enclosure in a side mounted manner. A thermally conductive material is used to connect a surface of the RTD to the inside surface to provide rapid thermal conduction from the enclosure to the RTD.

This Summary is an overview of some of the teachings of the present application and not intended to be an exclusive or exhaustive treatment of the present subject matter. Further details about the present subject matter are found in the detailed description and appended claims. The scope of the present invention is defined by the appended claims and their legal equivalents.

### BRIEF DESCRIPTION OF THE DRAWINGS

FIG. 1A shows a temperature sensor using a thin film resistance temperature detector (RTD), according to one embodiment of the present subject matter.

FIG. 1B shows a close-up of FIG. 1A at 1B-1B illustrating a particular thin film element adapted for soldering to the metal enclosure according to one embodiment of the present subject matter.

FIGS. 2A and 2B illustrate a cross section of FIG. 1A at 2A-2A showing variations in designs using different sizes of side mounted thin film elements with respect to similar sized enclosures, according to various embodiments of the present subject matter.

### DETAILED DESCRIPTION

The following detailed description of the present subject matter refers to subject matter in the accompanying drawings which show, by way of illustration, specific aspects and embodiments in which the present subject matter may be practiced. These embodiments are described in sufficient detail to enable those skilled in the art to practice the present subject matter. References to “an”, “one”, or “various” embodiments in this disclosure are not necessarily to the same embodiment, and such references contemplate more than one embodiment. The following detailed description is demonstrative and not to be taken in a limiting sense. The scope of the present subject matter is defined by the appended claims, along with the full scope of legal equivalents to which such claims are entitled.

The present subject matter of the invention relates generally to temperature sensors using thin film resistance temperature detectors (RTDs).

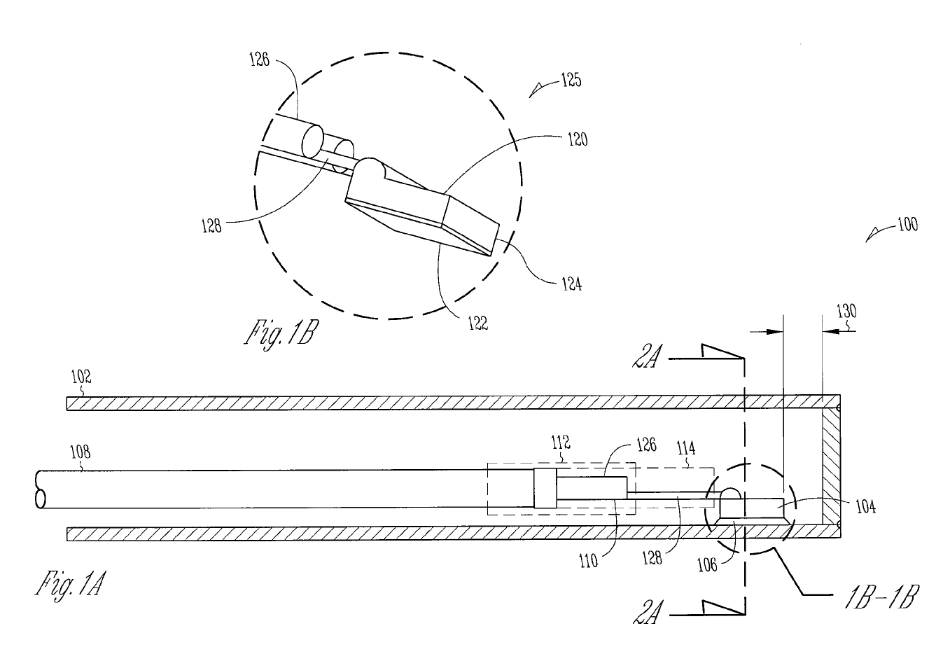

FIG. 1A shows a temperature sensor using a thin film resistance temperature detector (RTD), according to one embodiment of the present subject matter. Sensor assembly 100 includes an enclosure 102 surrounding a thin film element 104, the thin film element 104 having a surface that is attached to the enclosure 102 using a thermally conductive material 106. In one embodiment the thermally conductive material 106 is a thermally conductive adhesive. Various types of adhesives include, but are not limited to silicone or epoxy adhesives. In one embodiment the thermally conductive material 106 is solder. One of the advantages of this approach is that the temperature experienced by enclosure 102 is rapidly sensed by thin film element 104 because of the thermal conduction of the material 106. In various embodiments, the thermal conductivity of material 106 is selected to provide thermal transfer at a desired rate, such as a rate that is commensurate with a given control loop specification. Such designs will be referred to as “side mounted” thin film element designs. In one embodiment, the surface of the thin film element 104 is completely covered by the thermally conductive material 106. In various embodiments, the thin film element 104 has a number of sizes and shapes. In one embodiment, the surface of the thin film element 104 is rectangular. In another embodiment, the surface of the thin film element 104 is square. In one embodiment, the surface of the thin film element 104 is 1 mm by 1 mm. In another embodiment, the surface of the thin film element 104 is 5 mm by 5 mm. In various embodiments, the surface of the thin film element 104 has dimensions in a range between approximately 1 mm by 1 mm and approximately 5 mm by 5 mm. It is understood that other shapes and sizes of the thin film element 104 can be used without departing from the scope of the present subject matter.

In various embodiments, thin film element is a thin film RTD. One advantage of this design is that the sensed temperature can be rapidly measured by the thin film element in proximity to the enclosure. The side mounted design reduces the mass of the sensor and/or potting material over other designs to provide as short a “thermal path” to the sensor as possible. The reduced mass increases thermal response which is important for low heat transfer applications, such as stagnant or slow moving fluids. Such designs also provide improved temperature sensing over a variety of applications, including, but not limited to moving fluids (such as boiling). Another advantage is that thin film RTD's also feature better reliability than hollow wound sensor designs and therefore provide a robust design over several temperature cycles.

Another advantage is that such “side mounted” designs can be accomplished with fewer connections than the hollow wound designs, also enhancing reliability. In various embodiments, the thin film element 104 is connected to leadwires 108 for electrically sensing temperature proximal the thin film element 104. In one embodiment, leads 128 are connected to the thin film forming the RTD on thin film element 104. Wires 126 are connected to the leads 128 by methods including, but not limited to soldering or spot welding. Various insulations 112 and 114 may be used to electrically insulate the wires connecting leadwire 108 to thin film element 104. This prevents electrical shorting of the wires together, to other components, and to the enclosure 102.

FIG. 1B shows a close-up drawing of a particular thin film element adapted for soldering to the enclosure according to one embodiment of the present subject matter. Thin film element 125 includes a thin film 120 patterned on one side of a substrate 124. The other side of the substrate includes a plated backing 122 adapted for solder mounting to another surface, such as the enclosure. The thin film 120 is electrically connected to leads 128 which can be connected to wires 126. Various interconnection approaches include, but are not limited to spot welding and soldering. Other shapes, connections, and configurations are possible without departing from the scope of the present subject matter.

Various embodiments of the enclosure 102 include a metal case tubing having a thin wall. In one embodiment, the wall thickness is 0.016 inches or less. Thinner walled designs allow for more rapid temperature sensing than thicker walled designs. In one embodiment, the enclosure includes stainless steel. Different metals and other nonmetal enclosure materials may be used which offer different thermal transfer characteristics, specific heats, and thermal masses. Other wall thicknesses, enclosure shapes, and materials can be used without departing from the scope of the present subject matter.

The thin film element can be positioned in different locations along the enclosure. In one embodiment, the thin film element is separated by a gap 130 from the distal end of the enclosure to provide some thermal isolation of the thin film from close contact with the distal end of the enclosure. In one embodiment, a gap 130 of at least 1/16 inch between the thin film element and the wall of the enclosure proximal the thin film is employed. Other locations and gaps are possible without departing from the scope of the present subject matter.

The present subject matter is demonstrated using a single thin film element. It is understood that sensor assemblies using a plurality of thin film elements are possible without departing from the scope of the present subject matter. It is further understood that in various embodiments the thin film elements include a plurality of elements that are different in size. In various embodiments, the thin film elements include a plurality of elements that are uniform in size. Various location positions, configurations, and geometries are possible without departing from the scope of the present subject matter.

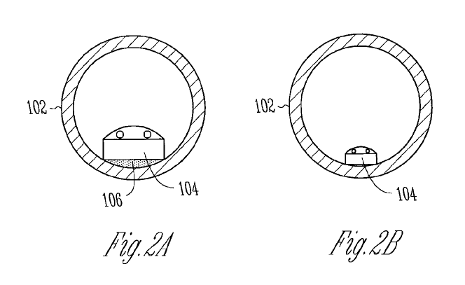

FIGS. 2A and 2B show that the proportion of the thin film element 104 with respect to the dimensions of the enclosure 102 can result in different effective thermal masses and surface areas. FIG. 2A requires more thermally conducting material 106 to attach a thin film element 104 which is larger with respect to the diameter of enclosure 102 than is necessary for the smaller thin film element of FIG. 2B.

In various embodiments a side wall thin film element sensor assembly can be connected using two spot weld or solder connections 110 provided that the leads of the thin film element are already connected, or using four connections if they are not. Consequently, either approach requires fewer connections than the 5 to 9 connections necessary for a hollow wound sensor design. Thus, manufacture of the present design is more streamlined and the resulting design is more robust.

This application is intended to cover adaptations or variations of the present subject matter. It is to be understood that the above description is intended to be illustrative, and not restrictive. The scope of the present subject matter should be determined with reference to the appended claims, along with the full scope of legal equivalents to which such claims are entitled.

What is claimed is:

1. A temperature sensor assembly, comprising:
an enclosure having an inside surface; and
a thin film element housed in the enclosure, wherein a thermally conductive material connects a surface of the thin film element directly to the inside surface of the enclosure in a side mounted manner to provide rapid thermal conduction from the enclosure to the thin film element.

2. The assembly of claim 1, wherein the enclosure includes a metal enclosure.

3. The assembly of claim 1, wherein the enclosure includes a cylindrical enclosure.

4. The assembly of claim 1, wherein the thin film element includes a thin film resistance temperature detector (RTD).

5. The assembly of claim 1, wherein the thermally conductive material includes a thermally conductive adhesive.

6. The assembly of claim 5, wherein the thermally conductive adhesive includes a silicone adhesive.

7. The assembly of claim 5, wherein the thermally conductive adhesive includes an epoxy adhesive.

8. The assembly of claim 1, wherein the surface of the thin film element is completely covered by the thermally conductive material.

9. The assembly of claim 1, wherein the surface of the thin film element is rectangular in shape and has dimensions ranging from approximately 1 mm by 1 mm to approximately 5 mm by 5 mm.

10. The assembly of claim 1, wherein the thermally conductive material includes solder.

11. The assembly of claim 1, wherein the thermally conductive material is selected to provide thermal transfer from the enclosure to the thin film element at a desired rate.

12. The assembly of claim 1, wherein the thin film element includes a substrate having a thin film patterned on a first side and a plated backing on a side opposite the first side, the plated backing adapted for mounting to the inside surface of the enclosure.

13. The assembly of claim 1, wherein the enclosure has a wall thickness of approximately 0.016 inches or less.

14. The assembly of claim 1, further comprising a plurality of thin film elements side mounted to the inside surface of the enclosure.

15. The assembly of claim 14, wherein the plurality of thin film elements includes thin film elements that are uniform in size.

16. A method of making a temperature sensor assembly, the method comprising:
connecting a surface of a thin film resistance temperature detector (RTD) directly to the inside surface of a thin-walled cylindrical metal enclosure in a side mounted manner using a thermally conductive material to provide rapid thermal conduction from the enclosure to the RTD.

17. The method of claim 16, further comprising separating the thin film RTD from a distal end of the enclosure to provide thermal insulation to the thin film RTD.

18. The method of claim 17, comprising separating the thin film RTD by at least approximately 1/16 of an inch from the distal end of the enclosure proximal the thin film RTD.

19. The method of claim 16, further comprising connecting leads to the thin film RTD and connecting wires to the leads.

20. The method of claim 16, further comprising minimizing mass of the thin film RTD and surrounding structure to provide rapid thermal conduction from the metal enclosure to the thin film RTD.
